(19) United States
(12) Patent Application Publication
(10) Pub. No.: US 2026/0047388 A1
(43) Pub. Date: Feb. 12, 2026

(54) WAFER CARRIER WITH AUTOMATION POSITIONING SYSTEM

(71) Applicant: ENTEGRIS, INC., Billerica, MA (US)

(72) Inventors: Mohamad Zakaria Abd Mutholib, Kulim (MY); Sin Ghun Lim, Butterworth (MY); Hang Khim Tan, Bukit Mertajam (MY)

(21) Appl. No.: 19/292,826

(22) Filed: Aug. 6, 2025

Related U.S. Application Data
(60) Provisional application No. 63/680,032, filed on Aug. 6, 2024.

(51) Int. Cl. H01L 21/677; H01L 21/673

(52) U.S. Cl. CPC H01L 21/67775; H01L 21/6732; H01L 21/67772

(57) ABSTRACT

A substrate carrier includes a base and a cassette, where the cassette is fixed to the base. The cassette can formed integrally with the base, attached to the base using fasteners, attached to the base through a mechanical interface or otherwise attached. The base includes features configured to receive alignment features on automation for handling the substrate carrier. The features configured to receive the alignment features can be three channels. The substrate carrier can be included in a substrate container having a pod dome configured to receive the base to enclose an open end, the base being a pod door of the substrate container.

### FIELD

This disclosure is directed to a substrate carrier configured to interface with alignment projections used in automation systems.

### BACKGROUND

Substrate containers include a door and a separate substrate carrier, such as a cassette. Automation systems may use alignment features such as kinematic coupling to interface with cassettes, which can require a separate adapter for use with the cassette during handling of the cassette.

### SUMMARY

This disclosure is directed to a substrate carrier configured to interface with alignment projections used in automation systems.

By providing an adapter capable of interfacing with the automation system fixed to the cassette, handling of substrate carriers can be facilitated, removing the need to handle and store a separate adapter and allowing the positioning of the substrate carrier to be made more precise using the alignment features. The improved precision in positioning of the substrate carrier can improve the reliability of the transfer of substrates to and from the substrate carrier. Further, the adapter can fix a position of the substrate carrier within a substrate container so as to reduce or avoid movement of the substrate carrier within the substrate container, for example due to transportation, handling, shock events such as drops, and the like. Additionally, the adapter can allow a container such as a standard mechanical interface (SMIF) pod to be simplified by replacing a separate cassette and a door with a single piece substrate carrier capable of enclosing the opening of the container.

In an embodiment, an article includes a substrate carrier. The substrate carrier includes a base. The base includes a plurality of openings, each of the plurality of openings configured to receive at least one of a plurality of alignment features. The substrate carrier further includes a cassette. The cassette includes a first side wall, a second side wall, and a top wall, the first and second side walls each including one or more substrate supports defining slots configured to receive a substrate. The cassette is fixed to the base.

In an embodiment, the article further includes a pod dome, the pod dome configured to accommodate the cassette in an internal space, the pod dome including an open end configured to receive the base so as to enclose the cassette within the pod dome and the base.

In an embodiment, the cassette is fixed to the base by one or more fasteners.

In an embodiment, the cassette is integral with the base.

In an embodiment, the cassette includes one or more first engagement features, the base includes one or more second engagement features, and the cassette is fixed to the base through engagement of the first engagement features with respective second engagement features.

In an embodiment, the plurality of openings includes at least three openings.

In an embodiment, the plurality of alignment features are features of a load port.

In an embodiment, the base includes a radio frequency identification (RFID) tag.

In an embodiment, a perimeter of the base does not extend beyond a perimeter of the cassette

In an embodiment, a substrate container includes a pod door. The pod door includes a plurality of openings, each of the plurality of openings configured to receive at least one of a plurality of alignment features. The substrate container further includes a cassette configured to accommodate one or more substrates, the cassette fixed to the pod door. The substrate container further includes a pod dome, the pod dome configured to accommodate the cassette in an internal space, the pod dome including an open end configured to receive the pod door so as to enclose the cassette within the pod dome and the pod door.

In an embodiment, the cassette is fixed to the pod door by one or more fasteners.

In an embodiment, the cassette is integral with the pod door.

In an embodiment, the cassette includes one or more first engagement features, the pod door includes one or more second engagement features, and the cassette is fixed to the pod door through engagement of the first engagement features with respective second engagement features.

In an embodiment, the plurality of openings includes at least three openings.

In an embodiment, the plurality of alignment features are features of a load port.

In an embodiment, the base includes a radio frequency identification (RFID) tag.

In an embodiment the substrate container consists of the pod door, the cassette, and the pod dome.

In an embodiment, the substrate container is a standard mechanical interface (SMIF) pod.

### DRAWINGS

FIG. 1 shows an exploded view of a substrate container according to an embodiment.

FIG. 2A shows a substrate carrier according to an embodiment.

FIG. 2B shows a bottom view of the substrate carrier of FIG. 2A.

FIG. 3A shows a substrate carrier according to an embodiment.

FIG. 3B shows a bottom view of the substrate carrier of FIG. 3A.

FIG. 4A shows a substrate carrier according to an embodiment.

FIG. 4B shows a bottom view of the substrate carrier of FIG. 4A.

FIG. 5 shows a load port configured to be used with a substrate carrier according to an embodiment.

### DETAILED DESCRIPTION

This disclosure is directed to a substrate carrier configured to interface with alignment projections used in automation systems.

As used herein, elements being “fixed” to one another means that elements are attached such that there is minimal or no relative movement among the elements fixed to one another when one element is moved or subjected to force. Minimal movement is understood as including deflection of one or both of the fixed articles, minor movements due to tolerances or loosening over time of fasteners or mechanical engagements, or the like. Elements can be fixed to one another by being formed as one integral piece, or through suitable attachments including mechanical fasteners, engagement of mechanical features such as slots, tabs, flanges, snap-fit features, or the like, adhesives, combinations thereof, and the like.

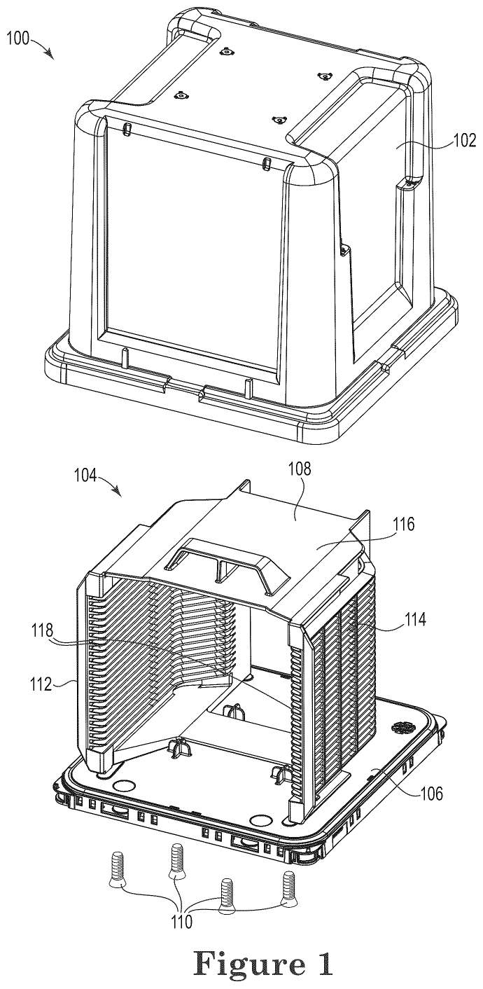

FIG. 1 shows an exploded view of a substrate container according to an embodiment. Substrate container 100 includes a pod dome 102 and a substrate carrier 104 including a pod door 106 and a cassette 108.

Substrate container 100 can be a container configured to accommodate one or more substrates, for example for storage and/or transport of said substrates. The substrates can be substrates being processed, for example, in semiconductor manufacture. A non-limiting example of substrate container 100 is a standard mechanical interface (SMIF) pod.

Pod dome 102 is configured to surround the substrate carrier. Pod dome 102 can include an open end at a bottom of the pod dome 102, and side walls and a top wall opposite the open end defining an internal space capable of accommodating the substrate carrier 104.

Substrate carrier 104 includes pod door 106 and cassette 108. In substrate carrier 104, the pod door 106 is fixed to the cassette 108. The pod door 106 is fixed to cassette 108 by any suitable connection, with non-limiting examples including pod door 106 and cassette 108 being formed integrally with one another, pod door 106 and cassette 108 being mechanically attached to one another by suitable corresponding engagement features such as snap-fit features, slots, tabs, flanges, or the like, or attached to one another using one or more fasteners 110 as shown in FIG. 1.

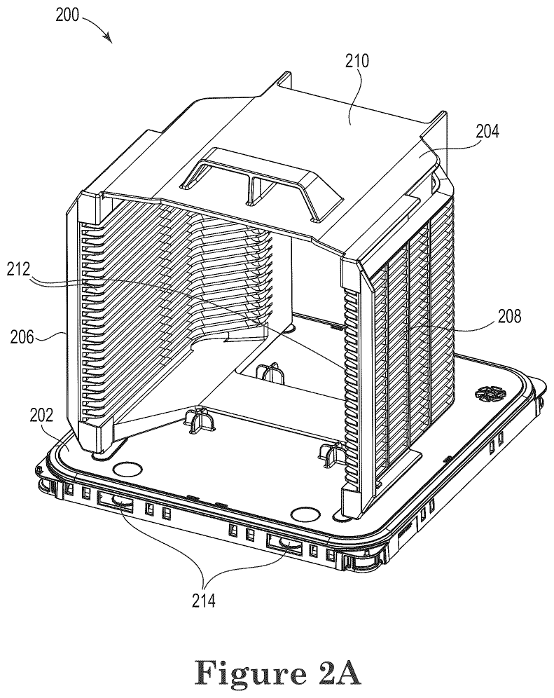

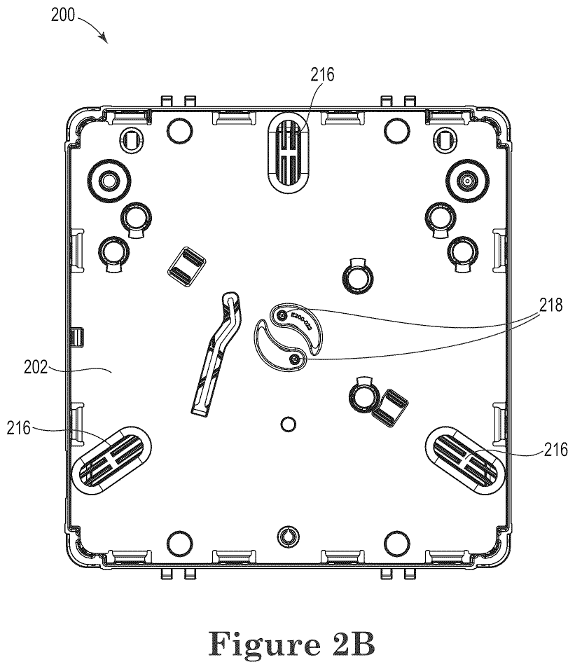

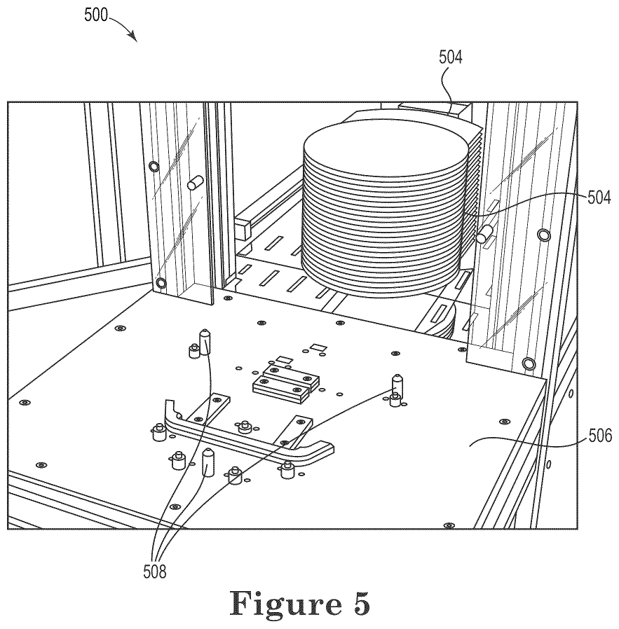

Pod door 106 is configured to enclose the open end of pod dome 102. Pod door 106 can be received in the open end of pod dome 102 so as to enclose pod dome 102 with cassette 108 within an internal space defined by the pod dome 102 and pod door 106. The pod door 106 can include any suitable latching features and corresponding actuation features, for example as shown in FIGS. 2A and 2B and described below. The pod door 106 includes a plurality of openings configured to receive alignment features such as alignment pins provided at a load port of a processing tool. A non-limiting example of a load port and the alignment pins thereof is provided in FIG. 5 and described below. The openings provided in pod door 106 can be channels, recesses, cutouts, or any other suitable feature capable of receiving the alignment features. The shape, position, and orientation of the openings can be such that the substrate carrier 104 is positioned and oriented so as to interface with automation at the load port. An example of the openings provided on pod door 106 can be seen in FIG. 2B and is described below.

Cassette 108 is configured to contain substrates. Cassette 108 is configured to be accommodated within an internal space of container 100 defined by the pod dome 102 and pod door 106. Cassette 108 can include opposing first and second side walls 112, 114 and a top wall 116 defining a space capable of accommodating the substrates. Cassette 108 can include a plurality of substrate supports 118 on each of the opposing first and second side walls. The substrate supports can define slots configured to allow a substrate to be positioned within each slot, resting on a pair of substrate supports 118 respectively disposed opposite one another on first and second side walls 112, 114. Cassette 108 is fixed to a base, with the base as shown in the embodiment of FIG. 1 being the pod door 106.

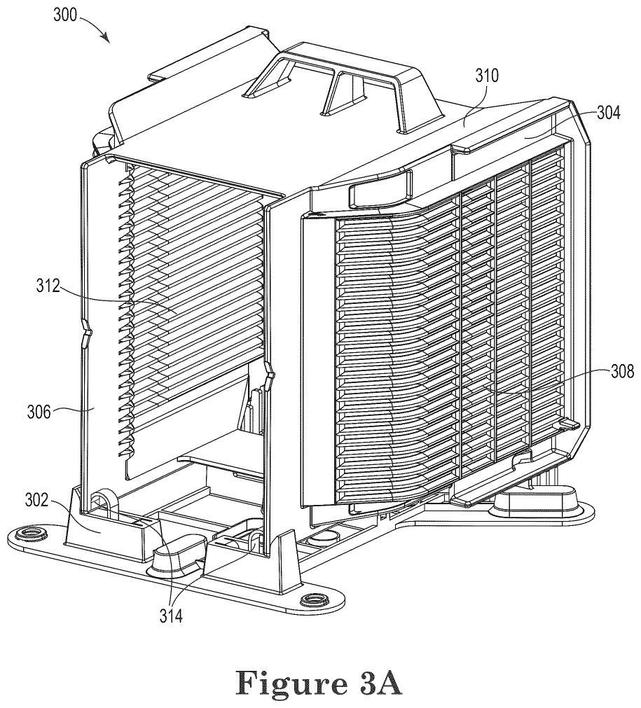

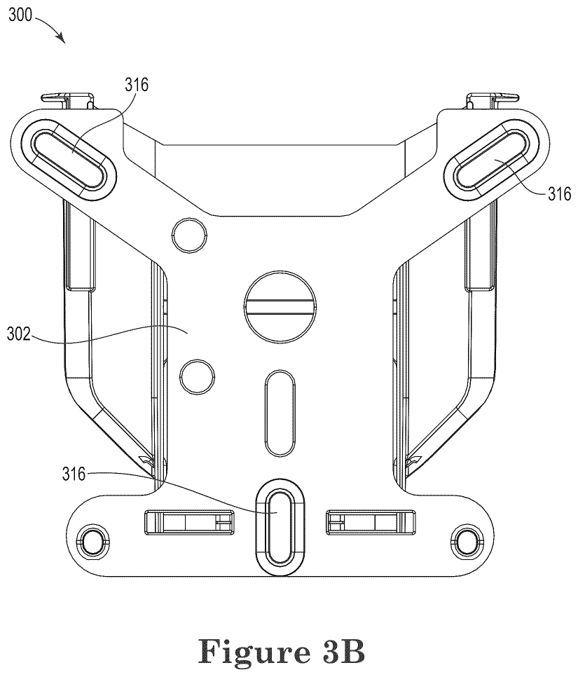

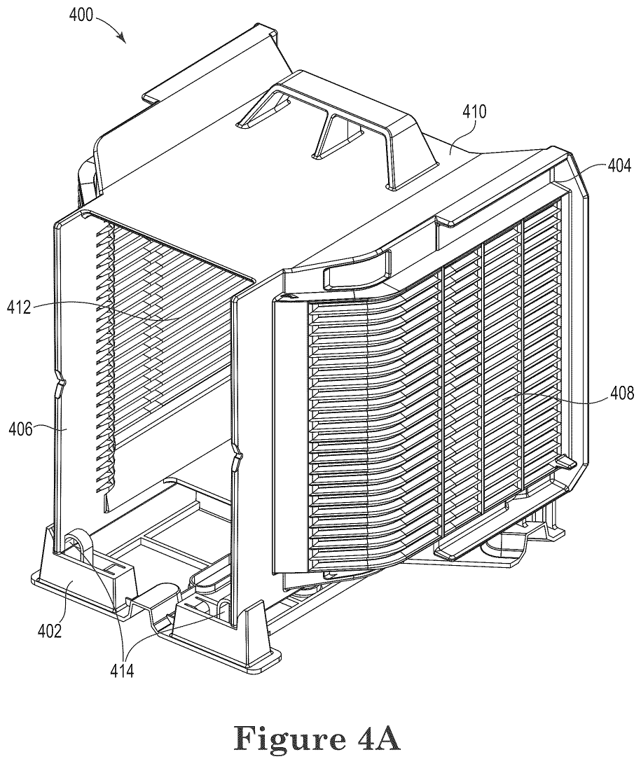

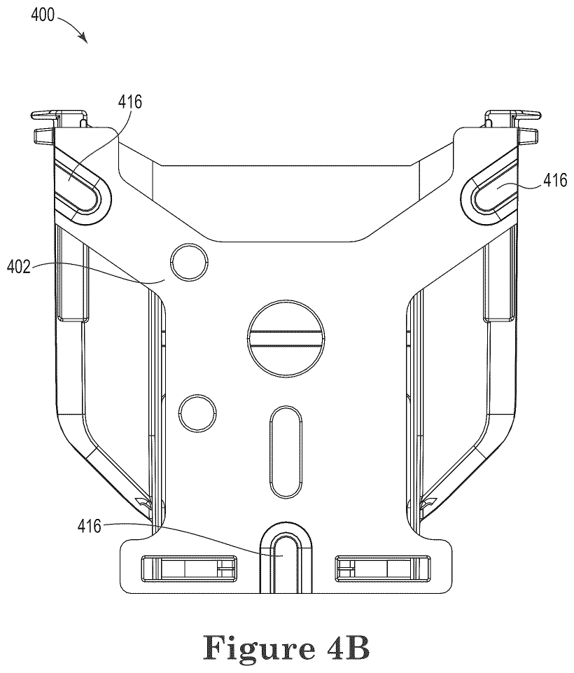

Fasteners 110 can be used to fix the cassette 108 to pod door 106 in an embodiment. Fasteners 110 can be any suitable mechanical fasteners for affixing the cassette 108 to pod door 106, such as the screws as shown in FIG. 1. Alternatively, fasteners 110 can be omitted, for example where mechanical engagement features are included directly in pod door 106 and cassette 108, or when the pod door 106 and cassette 108 are formed integrally with one another, for example as a unitary substrate carrier element. In an embodiment, instead of securing pod door 106 to cassette 108, the fasteners 110 can be used to fix another base that is not a pod door such as pod door 106 to the cassette, for example such fasteners being used to fix the bases 304 and 404 described below and shown in FIGS. 3A, 3B, 4A, and 4B to the respective cassettes 302, 402.

FIG. 2A shows a substrate carrier according to an embodiment. Substrate carrier 200 includes pod door 202 and cassette 204. Cassette 204 includes first side wall 206, second side wall 208, top wall 210, and substrate supports 212. The pod door 202 includes latching features 214.

Substrate carrier 200 is configured to be used to contain one or more substrates, for example during storage, transportation, and the like. Substrate container 200 can be configured to be joined to a pod dome to form a substrate container, such as the substrate container 100 as described above and shown in FIG. 1.

Pod door 202 is configured to enclose a substrate container, such as substrate container 100 as described above and shown in FIG. 1, by enclosing an open end of a pod dome. The pod door 202 is further configured to be removed from the pod dome and to be moved with the cassette 204 in handling of the substrate carrier 200. As shown in FIG. 2B and described below, the pod door 202 includes openings 216 configured to receive alignment features, for example alignment features provided at a load port, with a non-limiting example of such features being shown in FIG. 5 and described below. The pod door 202 can include latching features 214 configured to engage a pod dome so as to secure the pod door 202 to the pod dome to enclose a substrate container. Latching features 214 can be controlled through manipulation of a latch actuator 218 on a bottom of the pod door 206, as can be seen in FIG. 2B.

Cassette 204 is fixed to the pod door 202. The cassette 204 can be fixed to the pod door through any suitable connection, with non-limiting examples being the cassette 204 and at least part of pod door 202 being formed integrally, attachment of cassette 204 to pod door 202 by one or more fasteners such as the fasteners 110 described above and shown in FIG. 1, engagement of corresponding mechanical engagement features, or the like. Cassette 204 includes an internal space configured to accommodate the one or more substrates, for example defining the internal space by first side wall 206, second side wall 208, and a top wall 210. The internal space can be open at least on a front side thereof, such that the substrates can be inserted into or removed from the internal space. The first and second side walls 206, 208 can include substrate supports 212. The substrate supports 212 can define slots each capable of receiving a substrate, and supporting the substrate within the internal space of cassette 204.

FIG. 2B shows a bottom view of the substrate carrier of FIG. 2A. In the bottom view of FIG. 2B, a bottom of the pod door 202 can be seen. The bottom of pod door 202 visible in FIG. 2B can face outwards from the container when substrate carrier 200 is joined to a pod dome to form a container. As can be seen in FIG. 2B, the pod door 202 includes openings 216 and latch actuator 218. Openings 216 are channels, recesses, cutouts, or any other suitable feature capable of receiving alignment features, such as substrate container alignment features provided at a load port as described below and shown in FIG. 5. The shape, position, and orientation of the openings 216 can be such that the substrate carrier 200 is positioned and oriented so as to interface with automation at the load port. The latch actuator 218 is configured to be engaged by a human user or automation so as to actuate the latching features 214 so as to secure or release pod door 202 to a corresponding pod dome.

FIG. 3A shows a substrate carrier according to an embodiment. Substrate carrier 300 includes base 302 and cassette 304. Cassette 304 includes first side wall 306, second side wall 308, top wall 310, and substrate supports 312. Base 302 includes retention features 314.

Base 302 is configured to be attached to cassette 304 so as to allow the cassette 304 to be aligned through interfacing of the base 302 with alignment features such as alignment features provided at a load port, with a non-limiting example of such features being shown in FIG. 5 and described below. Base 302 can interface with such alignment features at openings 316 provided on a bottom side of base 302, visible in the bottom view of FIG. 3B and described below. In an embodiment, the base 302 and/or cassette 304 can be configured such that the base 302 and cassette 304 can fit within a substrate container defined by a pod dome and a pod door, such as, as a non-limiting example, a standard mechanical interface (SMIF) pod. The base 302 can include one or more retention features 314 configured to engage cassette 304 so as to fix the base 302 to the cassette 304. The retention features 314 can include, for example, clips, flanges, tabs, snap-fit features, or any other suitable mechanical engagement features. In the embodiment shown in FIGS. 3A and 3B, the base can have a footprint greater than a footprint of the cassette 304, the perimeter of base 302 extending beyond a perimeter of the cassette 304 when the substrate carrier 300 is viewed in a plan view or in the bottom view shown in FIG. 3B.

Cassette 304 is fixed to the base 302. The cassette 304 can be fixed to the base through any suitable connection, with non-limiting examples being the cassette 304 and at least part of base 302 being formed integrally, attachment of cassette 304 to base 302 by one or more fasteners such as the fasteners 110 described above and shown in FIG. 1, engagement of corresponding mechanical engagement features, or the like. In the embodiment shown in FIG. 3A, the cassette 304 is fixed to the base 302 by contact of retention features 314 of the base 302 with portions of the cassette 304. Cassette 304 includes an internal space configured to accommodate the one or more substrates, for example defining the internal space by first side wall 306, second side wall 308, and a top wall 310. The internal space can be open at least on a front side thereof, such that the substrates can be inserted into or removed from the internal space. The first and second side walls 306, 308 can include substrate supports 312. The substrate supports 312 can define slots each capable of receiving a substrate, and supporting the substrate within the internal space of cassette 304.

FIG. 3B shows a bottom view of the substrate carrier of FIG. 3A. In FIG. 3B, the base 302 can be seen. Base 302 has a footprint greater than that of cassette 304, beyond a perimeter of the cassette 304 at points, as visible in FIG. 3B. In FIG. 3B, openings 316 on a bottom of base 302 can be seen. Openings 316 are channels, recesses, cutouts, or any other suitable feature capable of receiving alignment features, such as substrate container alignment features provided at a load port as described below and shown in FIG. 5. The shape, position, and orientation of the openings 316 can be such that the substrate carrier 300 is positioned and oriented so as to interface with automation at the load port.

FIG. 4A shows a substrate carrier according to an embodiment. Substrate carrier 400 includes base 402 and cassette 404. Cassette 404 includes first side wall 406, second side wall 408, top wall 410, and substrate supports 412. Base 402 includes retention features 414.

Base 402 is configured to be attached to cassette 404 so as to allow the cassette 404 to be aligned through interfacing of the base 402 with alignment features such as alignment features provided at a load port, with a non-limiting example of such features being shown in FIG. 5 and described below. Base 402 can interface with such alignment features at openings 416 provided on a bottom side of base 402, visible in the bottom view of FIG. 4B and described below. In an embodiment, the base 402 and/or cassette 404 can be configured such that the base 402 and cassette 404 can fit within a substrate container defined by a pod dome and a pod door, such as, as a non-limiting example, a standard mechanical interface (SMIF) pod. The base 402 can include one or more retention features 414 configured to engage cassette 404 so as to fix the base 402 to the cassette 404. The retention features 414 can include, for example, clips, flanges, tabs, snap-fit features, or any other suitable mechanical engagement features. In the embodiment shown in FIGS. 4A and 4B, the base can have a footprint greater than a footprint of the cassette 404, the perimeter of base 402 extending beyond a perimeter of the cassette 404 when the substrate carrier 400 is viewed in a plan view or in the bottom view shown in FIG. 4B.

Cassette 404 is fixed to the base 402. The cassette 404 can be fixed to the base through any suitable connection, with non-limiting examples being the cassette 404 and at least part of base 402 being formed integrally, attachment of cassette 404 to base 402 by one or more fasteners such as the fasteners 110 described above and shown in FIG. 1, engagement of corresponding mechanical engagement features, or the like. Cassette 404 includes an internal space configured to accommodate the one or more substrates, for example defining the internal space by first side wall 406, second side wall 408, and a top wall 410. The internal space can be open at least on a front side thereof, such that the substrates can be inserted into or removed from the internal space. The first and second side walls 406, 408 can include substrate supports 412. The substrate supports 412 can define slots each capable of receiving a substrate, and supporting the substrate within the internal space of cassette 404.

FIG. 4B shows a bottom view of the substrate carrier of FIG. 4A. In FIG. 4B, the base 402 can be seen. Base 402 has a footprint smaller than that of cassette 404, with no portion of base 402 extending beyond a perimeter of the cassette 404 as visible in FIG. 4B. In FIG. 4B, openings 416 on a bottom of base 402 can be seen. Openings 416 are channels, recesses, cutouts, or any other suitable feature capable of receiving alignment features, such as substrate container alignment features provided at a load port as described below and shown in FIG. 5. The shape, position, and orientation of the openings 416 can be such that the substrate carrier 400 is positioned and oriented so as to interface with automation at the load port.

FIG. 5 shows a load port configured to be used with a substrate carrier according to an embodiment. Load port 500 includes transfer tool 502 configured to transfer substrates 504. Load port 500 further includes substrate carrier support 506 including substrate carrier alignment features 508.

Load port 500 is a portion of a substrate processing tool configured to facilitate the transfer of substrates 504 to and from substrate carriers such as the substrate carriers described herein. Transfer tool 502 can be provided at load port 500. Transfer tool 502 can include a number of supports configured to be inserted into a substrate carrier and capable of lifting the substrates 504 and withdrawing said substrates 504 from the respective slots provided in the substrate carrier. The supports of transfer tool 502 can also be used to place the substrates 504 into the substrate carrier, and lower the substrates 504 to rest on the substrate supports defining the respective slots for receiving the substrates 504.

Substrates 504 can be any suitable substrates, such as wafers, that are to be inserted into or removed from the substrate carrier. The substrates 504 can be processed in the tool including load port 500, for example in semiconductor manufacture.

Substrate carrier support 506 is a surface where the substrate carrier can be placed to allow transfer of substrates 504 into or out of the substrate carrier by transfer tool 502. Substrate carrier support 506 can include a plurality of substrate carrier alignment features 508. The substrate carrier alignment features are projections from the substrate carrier support 506. The substrate carrier can be configured to receive the substrate carrier alignment features 508, for example at a plurality of recesses or openings provided on a base included in the substrate carrier. In an embodiment, at least three substrate carrier alignment features 508 are provided, for example positioned to interface with kinematic coupling (KC) features provided on the base. The substrate carrier alignment features 508 can be configured such that when the substrate carrier receives the substrate carrier alignment features 508, the substrate carrier is positioned and aligned so as to interface with the transfer tool 502 at load port 500, such that the substrates 504 can be inserted into or removed from the substate carrier.

### ASPECTS

It is understood that any of aspects 1-9 can be combined with any of aspects 10-18.

Aspect 1. An article, comprising a substrate carrier, the substrate carrier including:
a base, the base including a plurality of openings, each of the plurality of openings configured to receive at least one of a plurality of alignment features; and
a cassette, the cassette including a first side wall, a second side wall, and a top wall, the first and second side walls each including one or more substrate supports defining slots configured to receive a substrate, the cassette fixed to the base.

Aspect 2. The article according to aspect 1, further comprising a pod dome, the pod dome configured to accommodate the cassette in an internal space, the pod dome including an open end configured to receive the base so as to enclose the cassette within the pod dome and the base.

Aspect 3. The article according to any of aspects 1-2, wherein the cassette is fixed to the base by one or more fasteners.

Aspect 4. The article according to any of aspects 1-3, wherein the cassette is integral with the base.

Aspect 5. The article according to any of aspects 1-4, wherein the cassette includes one or more first engagement features, the base includes one or more second engagement features, and the cassette is fixed to the base through engagement of the first engagement features with respective second engagement features.

Aspect 6. The article according to any of aspects 1-5, wherein the plurality of openings includes at least three openings.

Aspect 7. The article according to any of aspects 1-6, wherein the plurality of alignment features are features of a load port.

Aspect 8. The article according to any of aspects 1-7, wherein the base includes a radio frequency identification (RFID) tag.

Aspect 9. The article according to any of aspects 1-8, wherein a perimeter of the base does not extend beyond a perimeter of the cassette

Aspect 10. A substrate container, comprising:
a pod door, the pod door including a plurality of openings, each of the plurality of openings configured to receive at least one of a plurality of alignment features;
a cassette configured to accommodate one or more substrates, the cassette fixed to the pod door; and
a pod dome, the pod dome configured to accommodate the cassette in an internal space, the pod dome including an open end configured to receive the pod door so as to enclose the cassette within the pod dome and the pod door.

Aspect 11. The substrate container according to aspect 10, wherein the cassette is fixed to the pod door by one or more fasteners.

Aspect 12. The substrate container according to any of aspects 10-11, wherein the cassette is integral with the pod door.

Aspect 13. The substrate container according to any of aspects 10-12, wherein the cassette includes one or more first engagement features, the pod door includes one or more second engagement features, and the cassette is fixed to the pod door through engagement of the first engagement features with respective second engagement features.

Aspect 14. The substrate container according to any of aspects 10-13, wherein the plurality of openings includes at least three openings.

Aspect 15. The substrate container according to any of aspects 10-14, wherein the plurality of alignment features are features of a load port.

Aspect 16. The substrate container according to any of aspects 10-15, wherein the base includes a radio frequency identification (RFID) tag.

Aspect 17. The substrate container according to any of aspects 10-16, wherein the substrate container consists of the pod door, the cassette, and the pod dome.

Aspect 18. The substrate container according to any of aspects 10-17, wherein the substrate container is a standard mechanical interface (SMIF) pod.

The examples disclosed in this application are to be considered in all respects as illustrative and not limitative. The scope of the invention is indicated by the appended claims rather than by the foregoing description; and all changes which come within the meaning and range of equivalency of the claims are intended to be embraced therein.

1. An article, comprising a substrate carrier, the substrate carrier including:
a base, the base including a plurality of openings, each of the plurality of openings configured to receive at least one of a plurality of alignment features; and
a cassette, the cassette including a first side wall, a second side wall, and a top wall, the first and second side walls each including one or more substrate supports defining slots configured to receive a substrate, the cassette fixed to the base.

2. The article of claim 1, further comprising a pod dome, the pod dome configured to accommodate the cassette in an internal space, the pod dome including an open end configured to receive the base so as to enclose the cassette within the pod dome and the base.

3. The article of claim 1, wherein the cassette is fixed to the base by one or more fasteners.

4. The article of claim 1, wherein the cassette is integral with the base.

5. The article of claim 1, wherein the cassette includes one or more first engagement features, the base includes one or more second engagement features, and the cassette is fixed to the base through engagement of the first engagement features with respective second engagement features.

6. The article of claim 1, wherein the plurality of openings includes at least three openings.

7. The article of claim 1, wherein the plurality of alignment features are features of a load port.

8. The article of claim 1, wherein the base includes a radio frequency identification (RFID) tag.

9. The article of claim 1, wherein a perimeter of the base does not extend beyond a perimeter of the cassette.

10. A substrate container, comprising:
a pod door, the pod door including a plurality of openings, each of the plurality of openings configured to receive at least one of a plurality of alignment features;
a cassette configured to accommodate one or more substrates, the cassette fixed to the pod door; and
a pod dome, the pod dome configured to accommodate the cassette in an internal space, the pod dome including an open end configured to receive the pod door so as to enclose the cassette within the pod dome and the pod door.

11. The substrate container of claim 10, wherein the cassette is fixed to the pod door by one or more fasteners.

12. The substrate container of claim 10, wherein the cassette is integral with the pod door.

13. The substrate container of claim 10, wherein the cassette includes one or more first engagement features, the pod door includes one or more second engagement features, and the cassette is fixed to the pod door through engagement of the first engagement features with respective second engagement features.

14. The substrate container of claim 10, wherein the plurality of openings includes at least three openings.

15. The substrate container of claim 10, wherein the plurality of alignment features are features of a load port.

16. The substrate container of claim 10, wherein the base includes a radio frequency identification (RFID) tag.

17. The substrate container of claim 10, wherein the substrate container consists of the pod door, the cassette, and the pod dome.

18. The substrate container of claim 10, wherein the substrate container is a standard mechanical interface (SMIF) pod.
